(19) United States
(12) Patent Application Publication
(10) Pub. No.: US 2011/0199125 A1
(43) Pub. Date: Aug. 18, 2011

(54) VOLTAGE COMPARATOR, LIQUID CRYSTAL DISPLAY DRIVER HAVING THE SAME AND TRANSITION ACCELERATION METHOD THEREOF

(76) Inventors: Kai-Shu Han, Baoshan Township (TW); Yu-Lung Lo, New Taipei City (TW); Ko-Yang Tso, New Taipei City (TW)

(21) Appl. No.: 13/023,635

(22) Filed: Feb. 9, 2011

(30) Foreign Application Priority Data
Feb. 12, 2010 (TW) 099104690

(51) Int. Cl. H03K 5/24; H03H 11/16

(52) U.S. Cl. 327/74; 327/256

(57) ABSTRACT

A voltage comparator includes an input portion, an output portion, and a diverting portion. The input portion accepts a first voltage and a second voltage and then outputs a first current based on the first voltage and outputs a second current based on the second voltage. The output portion outputs a result signal based on a difference between the first current and the second current. The diverting portion is electrically connected to the input portion and diverts a portion of the higher current amongst the first current and the second current.

### BACKGROUND OF THE INVENTION

1. Field of the Invention

This invention relates to a voltage comparator and a transition acceleration method thereof, specifically to a voltage comparator of LCD driving circuit and a transition acceleration method thereof.

2. Description of the Prior Art

The voltage comparator for comparing two voltages is a very common electronic component used in the electronic circuit. The voltage comparator used in liquid crystal display driver integrated circuits requires a very short response time. However, transition errors cause conventional voltage comparators to have lower accuracy and require more time to switch the logic level of output signal.

FIG. 1A is a schematic view of a conventional voltage comparator. As FIG. 1A shows, the conventional voltage comparator includes a current source 10, a differential input pair 20, a first current mirror 30, a second current mirror 40, a third current mirror 50, and an output portion 60, wherein the differential input pair 20 further includes a first input portion 21 and a second input portion 22. The first input portion 21 and the second input portion 22 receive the first voltage Vin+ and the second voltage Vin−, respectively. The first voltage Vin+ and the second voltage Vin− are directly proportional to the magnitude of the first current 23 and the second current 24, respectively. The combined structure of the first current mirror 30 and the third current mirror 50 outputs a first result current 31 to the output portion 60 through the third current mirror 50 based on the first current 23, wherein the first current 23 and the first result current 31 have the same logic level. Similarly, the second current mirror 40 transmits a second result current 32 to the output portion 60 based on the second current 24, wherein the second current 24 and the second result current 32 have the same logic level. The output portion 60 then outputs a digital output signal OUT based on the difference between voltages generated by the first result current 31 and the second result current 32. If the first voltage Vin+ is substantially greater than the second voltage Vin−, the output signal OUT from the output portion 60 is at high level. On the other hand, when the first voltage Vin+ is substantially smaller than the second voltage Vin−, the output signal OUT from the output portion 60 is at low level. Furthermore, in the schematic view of FIG. 1A, both node W1 and node W2 have parasitic capacitance, wherein the first current 23 and the second current 24 can charge those parasitic capacitances and increase the voltages at node W1 and node W2.

FIG. 1B is a timing diagram of the voltage comparator illustrated in FIG. 1A, wherein W1 and W2 in FIG. 1B represents the voltages at node W1 and node W2 illustrated in FIG. 1A. Please refer to both FIG. 1A and FIG. 1B, in the duration of Data 1, the first voltage Vin+ is smaller than the second voltage Vin− and therefore the first current 23 generated by the first input portion 21 is smaller than the second current 24 generated by the second input portion 22. Therefore, the first current 23 will start discharging the parasitic capacitance at node W1, and the second current 24 will start charging the parasitic capacitance at the second node W2. As a result, the voltage difference between the first node W1 and the second node W2 becomes larger and larger. The voltage level of output signal OUT from the output portion 60 will change when the voltage difference between nodes W1 and W2 reaches a threshold ΔV1, wherein the threshold ΔV1 is a fixed value.

Furthermore, toward the end of Data 1 when the first voltage Vin+ is greater than the second voltage Vin−, the first current 23 will charge the parasitic capacitance at node W1 and the second current 24 will discharge the parasitic capacitance at the second node W2. In this way, the voltage difference between nodes W1 and W2 is also approaching toward the threshold ΔV1. The voltage level of the output signal OUT will change again after the above-mentioned voltage difference reaches the threshold ΔV1.

However, the electronic components used in the conventional voltage comparator are not ideal and therefore cannot respond to the electronic signal inputs instantly. In other words, the output signal OUT of the output portion 60 needs time to reflect the relationship change between the first voltage Vin+ and the second voltage Vin−. As FIG. 1B shows, the level of the output signal OUT will change whenever the voltage difference between nodes W1 and W2 reaches the threshold ΔV1. In this way, even if the relationship between the first voltage Vin+ and the second voltage Vin− changes, as long as the voltage difference between nodes W1 and W2 has not reached the threshold ΔV1, the level of output signal OUT will not change.

As FIG. 1B shows, when the Data 2 has a longer duration, voltage at the node W1 will continue to increase and the voltage at the second node W2 will continue to drop. Therefore the voltage difference between nodes W1 and W2 will continue to increase, becoming larger and larger. In this way, even if the relationship of the first voltage Vin+ and the second voltage Vin− changes in the duration of Data 3, the above-mentioned voltage difference will require more time to charge and discharge the nodes W1 and W2 to reach the threshold ΔV1. Therefore the output signal OUT from the output portion 60 will require more time to respond to the change in relationship between the first voltage Vin+ and the second voltage Vin−. This increase in response time will reduce the effective bandwidth of Data 3 and increase the possibility of sampling error as the back-end system processing the output signal OUT, restricting the system clock of the back-end system.

### SUMMARY OF THE INVENTION

It is an objective of the present invention to provide a voltage comparator with faster transition speed and lower operating current.

It is another objective of the present invention to provide a liquid crystal display driver with faster transition speed and lower operating current.

It is yet another objective of the present invention to provide a transition acceleration method for increasing the transition speed of a voltage comparator and decreasing the overall operating current of the voltage comparator.

The voltage comparator for comparing a first voltage and a second voltage according to one embodiment of the present invention includes an input portion, an output portion, a result transformation portion, and a diverting portion. The input portion generates a first current and a second current based on the first voltage and the second voltage, respectively. The output portion generates an analogue result signal according to the difference between the first current and the second current. The result transformation portion generates a digital result signal based on the analogue result signal, wherein the voltage level of the digital result signal represents the relationship between the first voltage and the second voltage. The diverting portion is electrically connected to the input portion and selectively diverts the first current or the second current based on the analogue result signal or the digital result signal. The diverting portion preferably has a switch or a variable resistor, which is selectively conducted to divert one of the first current and the second current based on the analogue result signal or the digital result signal.

In a different embodiment, the input portion includes a first input portion and a second input portion that generate a first current and a second current according to the first voltage and the second voltage, respectively. The diverting portion includes a first diverting portion and a second diverting portion. The first diverting portion and the second diverting portion are provided for current-diverting and electrically connected to the first input portion and the second input portion, respectively. Furthermore, the voltage comparator includes a phase shifter for generating an inverted digital result signal based on the digital result signal, wherein the digital result signal and the inverted digital result signal are inputted into the switch of the first diverting portion and the switch of the second diverting portion. In this way, only one of the first diverting portion and the second diverting portion can be electrically conducted, but is not limited thereto. In different embodiments, the phase shifter can generate an inverted analogue result signal based on the analogue result signal, wherein the analogue result signal and the inverted analogue result signal can be inputted into the first variable resistor of the first diverting portion and the second variable resistor of the second diverting to change the equivalent resistance of the first diverting portion and that of the second diverting portion.

### BRIEF DESCRIPTION OF THE DRAWINGS

FIG. 1A is a schematic view of a conventional voltage comparator;

FIG. 1B is a timing diagram of the voltage comparator illustrated in FIG. 1A;

FIG. 2 is a schematic view of the voltage comparator of the present invention;

FIG. 3 is a timing diagram of the voltage comparator illustrated in FIG. 2;

FIG. 4 and FIG. 5 are variation embodiments of the voltage comparator illustrated in FIG. 2;

FIG. 6 illustrate another embodiment of the voltage comparator of the present invention;

FIG. 7 is a timing diagram of the voltage comparator illustrated in FIG. 6;

FIG. 8 and FIG. 9 are variation embodiments of the voltage comparator illustrated in FIGS. 6; and

FIG. 10 is a flow chart of the transition acceleration method of a voltage comparator.

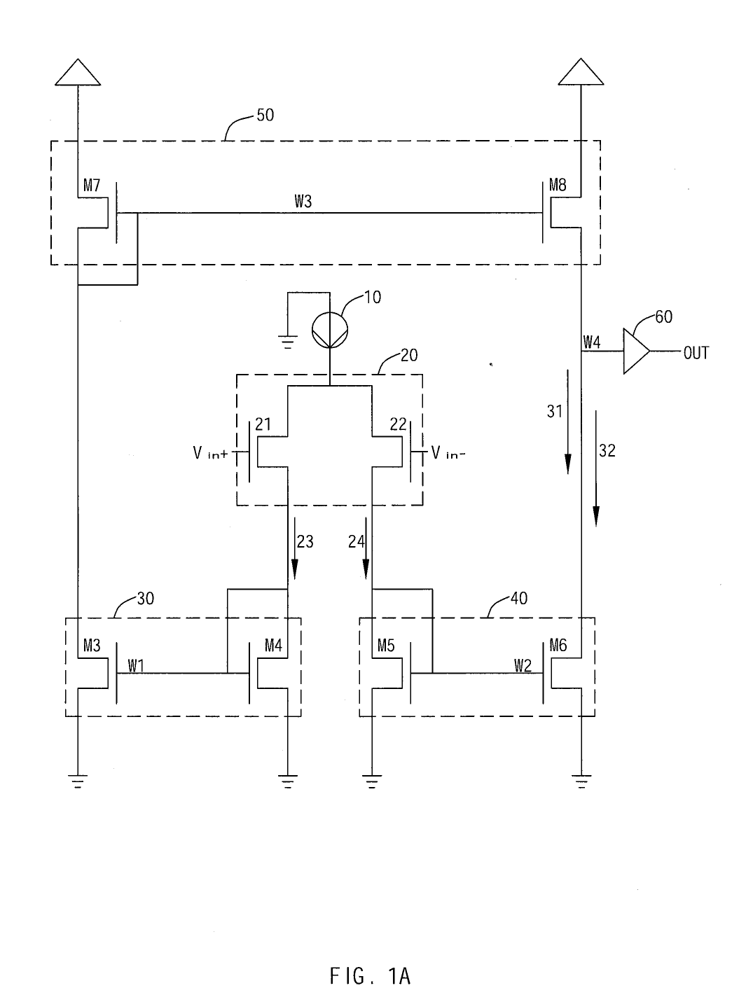

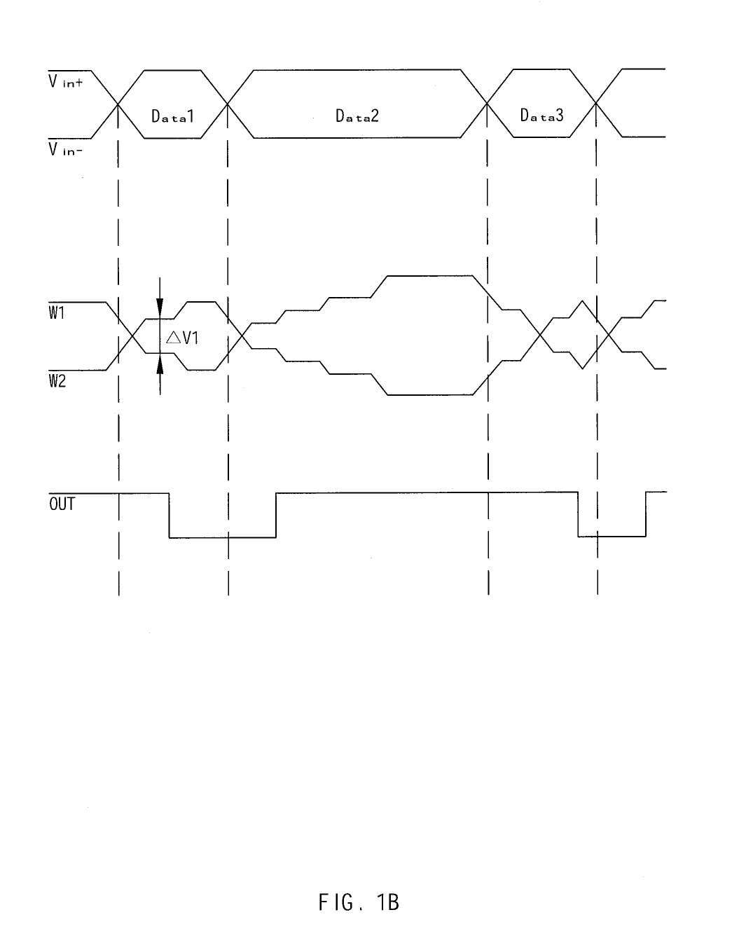

### DETAILED DESCRIPTION OF THE PREFERRED EMBODIMENT

The present invention discloses a voltage comparator and a transition acceleration method thereof, specifically a voltage comparator of a liquid crystal display driving circuit and a transition acceleration method thereof. The voltage comparator of the present invention increases the number of discharge paths of the current mirror and selectively discharges a portion of the current in the current mirror based on a voltage comparison result. With partial discharging of the current mirror, the voltage comparator reduces the voltage difference between two input points. In this way, when the logic levels of voltages at the two input ends reverse, the voltage at the output end of the voltage comparator requires less time to respond the change in voltage at the input ends.

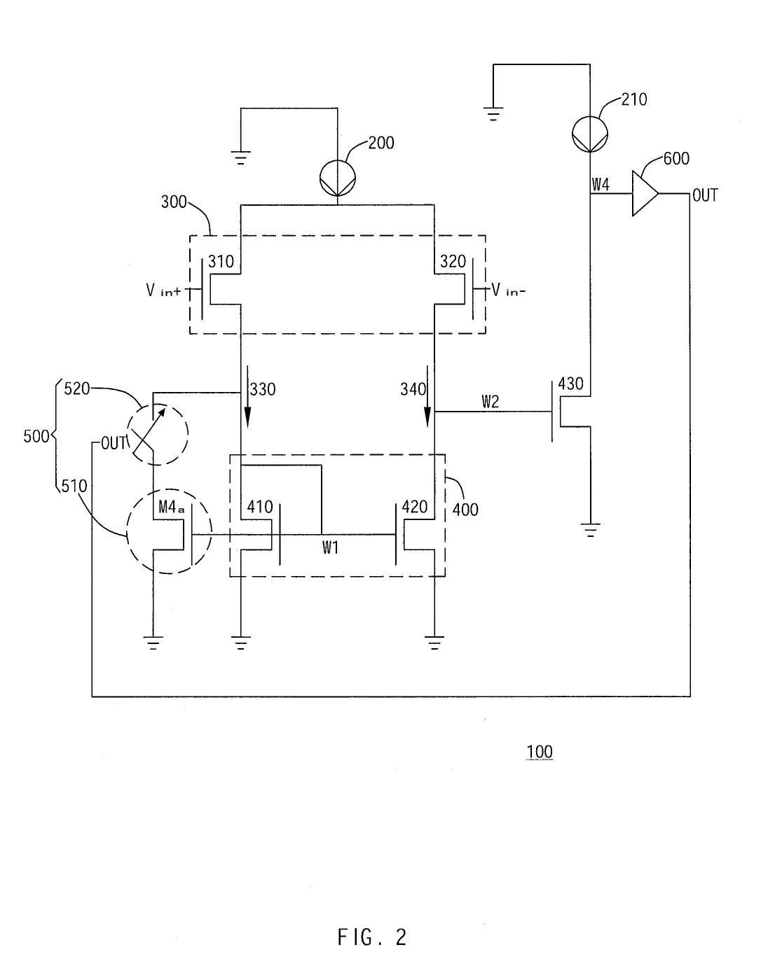

FIG. 2 is a schematic view of the voltage comparator 100 of the present invention. The voltage comparator 100 includes a first current source 200, a second current source 210, a voltage input portion 300, a result output portion 400, a diverting portion 500, and a result transformation portion 600. The voltage input portion 300 of the present embodiment is electrically connected to the first current source 200 and includes a first input portion 310 and a second input portion 320. The first input portion 310 and the second input portion 320 accept a first voltage Vin+ and a second voltage Vin−, respectively. The first input portion 310 and the second input portion 320 are selectively conducted and output a first current 330 and a second current 340 to the result output portion 400 based on the first voltage Vin+ and the second voltage Vin−.

In the present embodiment, the first input portion 310 and the second input portion 320 are both metal-oxide-semiconductor field-effect transistors (MOSFETs), but are not limited thereto; in different embodiments, the first input portion 310 and the second input portion 320 may include the bipolar junction transistors, the field-effect transistor, or other electronic components having switching function. In the embodiment illustrated in FIG. 2, the result output portion 400 includes a first output portion 410 and a second output portion 420, wherein the first output portion 410 and the second output portion 420 accept the first current 330 and the second current 340, respectively. The gate of the second output portion 420 is electrically connected to the source and the gate of first output portion 410. Therefore the amplitude of the first current 330 will affect the OPEN/CLOSED (i.e. non-conducted/conducted) status of the second output portion 420 and the voltage at the source of the second output portion 420. Furthermore, the first node W1 between gates of output portions 410, 420 and the second node W2 at the source of the second output portion 420 have parasitic capacitance. Therefore the first current 330 and the second current 340 will charge the parasitic capacitances at two nodes W1, W2 and increase the voltages at the two nodes W1, W2. Furthermore, in the present embodiment, the amplitude of first current 330 and the amplitude of the second current 340 are respectively proportional to the amplitude of the first voltage Vin+ and the amplitude of the second voltage Vin−, but are not limited thereto. In different embodiments, the ratio between two currents 330, 340 and the relationship between currents 330, 340 and the voltages Vin+, Vin− can vary based on the structure of the voltage comparator 100 and the transistors thereof.

As FIG. 2 shows, the result output portion 400 further includes a third output portion 430, wherein the source of the third output portion 430 is electrically connected to the second current source 210 and the result transformation portion 600. Therefore, the voltage at the source of the third output portion 430 will be inputted into the result transformation portion 600 for further processing. Furthermore, the gate of the third output portion 430 is electrically connected to the drain of the second input portion 320 and the source of second output portion 420. Therefore the voltage at the source of the second output portion 420 will control the OPEN/CLOSED status of the third output portion 430 and consequently the voltage received by the result transformation portion 600. In the present embodiment, the voltage at the second node W2 is an analogue voltage and this voltage will be transformed by the result transformation portion 600 into a digital voltage with a logic level, such as high level or low level.

Furthermore, as FIG. 2 shows, the diverting portion 500 includes a diverting transistor 510 and a switch 520, wherein the diverting transistor 510 of the present embodiment is a metal-oxide-semiconductor field-effect transistor (MOSFET). The source of the diverting transistor 510 is electrically connected to the source of first output portion 410 whereas the gate of the diverting transistor 510 is electrically connected to both the gate of the first output portion 410 and the gate of the second output portion 420. The switch 520 is controlled by the output of the result transformation portion 600. The output voltage of the result transformation portion 600 will be directly inputted into the switch 520 of the diverting portion 500, wherein the output voltage of the result transformation portion 600 is a digital signal of high level or low level. The switch 520 of the present embodiment conducts when the output voltage of the result transformation portion 600 is at high level so that the diverting portion 500 can divert a portion of the first current 330. The switch 520 opens when the output voltage of result transformation portion 600 is at low level. That is, the switch 520 of the present invention is used to selectively conduct or open according to the output signal of result transformation portion 600. For example, a portion of the first current 330 will flow to the diverting portion 500 when the switch 520 closes and conducts. In this way, the amount of first current 300 flowing to the first output portion 410 will decrease, wherein the ratio of the current flowing through the first output portion 410 and the current flowing through the diverting portion 500 is substantially equal to the ratio of equivalent resistances of the first output portion 410 and the diverting portion 500. In other words, the current flowing through the first output portion 410 and the current flowing through the diverting portion 500 can be regulated by changing the equivalent resistance of both the first output portion 410 and the diverting portion 500. As described above, the voltage comparator 100 uses the diverting portion 500 to distribute the first current 330 and consequently regulates the voltage at the first node W1. In this way, the voltage comparator 100 can reduce the response time required to switch the logic level of output voltage.

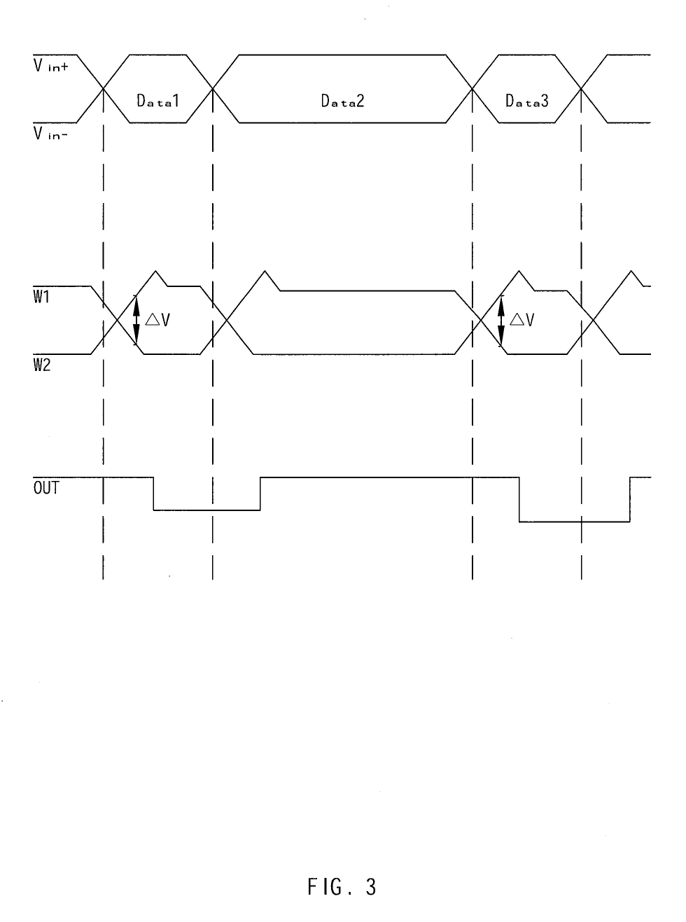

FIG. 3 is a timing diagram of the voltage comparator 100 illustrated in FIG. 2, wherein the first voltage Vin+, the second voltage Vin−, the output voltage OUT, and voltages at the first node W1 and the second node W2 are illustrated. Here please refer to both FIG. 2 and FIG. 3, in the duration of Data 2, the first voltage Vin+ is higher than the second voltage Vin−. Correspondingly, the first current 330 will increase and charge the parasitic capacitance at the first node W1 while the second current 340 decreases in magnitude and discharges the parasitic capacitance at the second node W2. In this way, the voltage at the first node W1 will increase while the voltage at the second node W2 decreases. Furthermore, when the difference of voltages between the first node W1 and the second node W2 reaches a threshold ΔV, the output voltage OUT outputted by the result transformation portion 600 will be switched from low level to high level. The output voltage OUT will close the switch 520 so that a portion of the first current 330 will flow through the diverting portion 500. The parasitic capacitance of the first node W1 will no longer increase and start decreasing. Accordingly, the parasitic capacitance of the first node W1 is not continuously charged by the first current 330 and will not continue increasing in the duration of Data 2. Thus, in the duration of Data 3 where the firs voltage Vin+ is lower than the second voltage Vin−, the voltage difference between the first node W1 and the second node W2 can reach the threshold ΔV1 earlier. This will reduce the response time required to switch the voltage level of the output signal OUT. In this way, when the first voltage Vin+ is higher than the second voltage Vin− (in the duration of Data 2), the voltage difference between the parasitic capacitances of the first node W1 and the second node W2 will require less time to reach the threshold ΔV1 and therefore the time required to switch the voltage level of the output signal OUT is reduced.

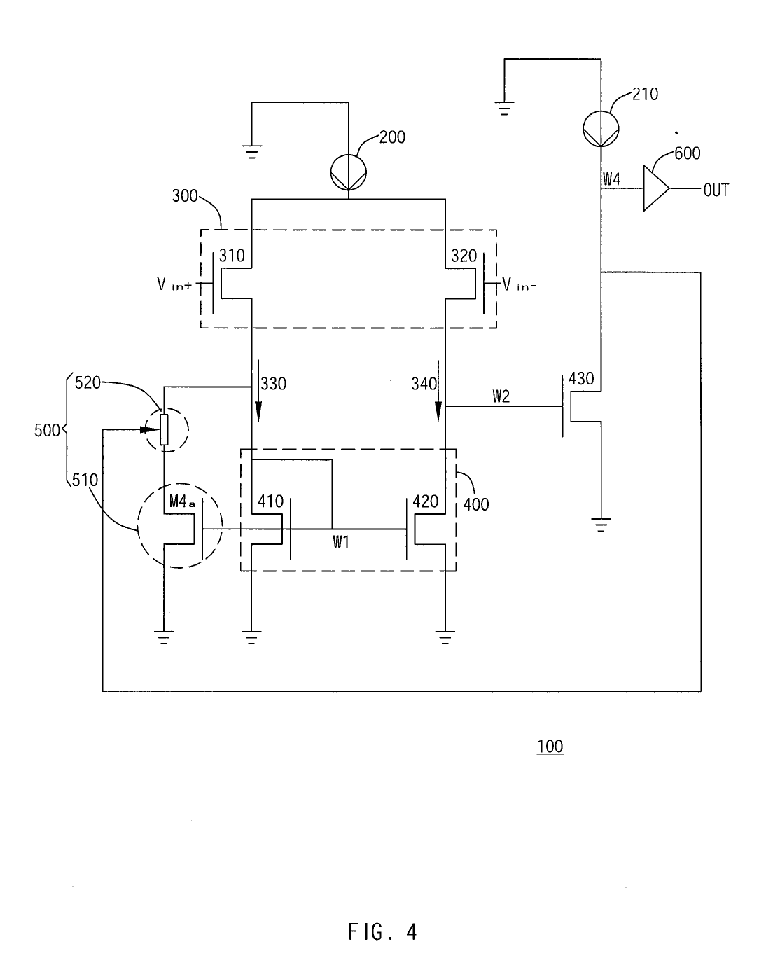

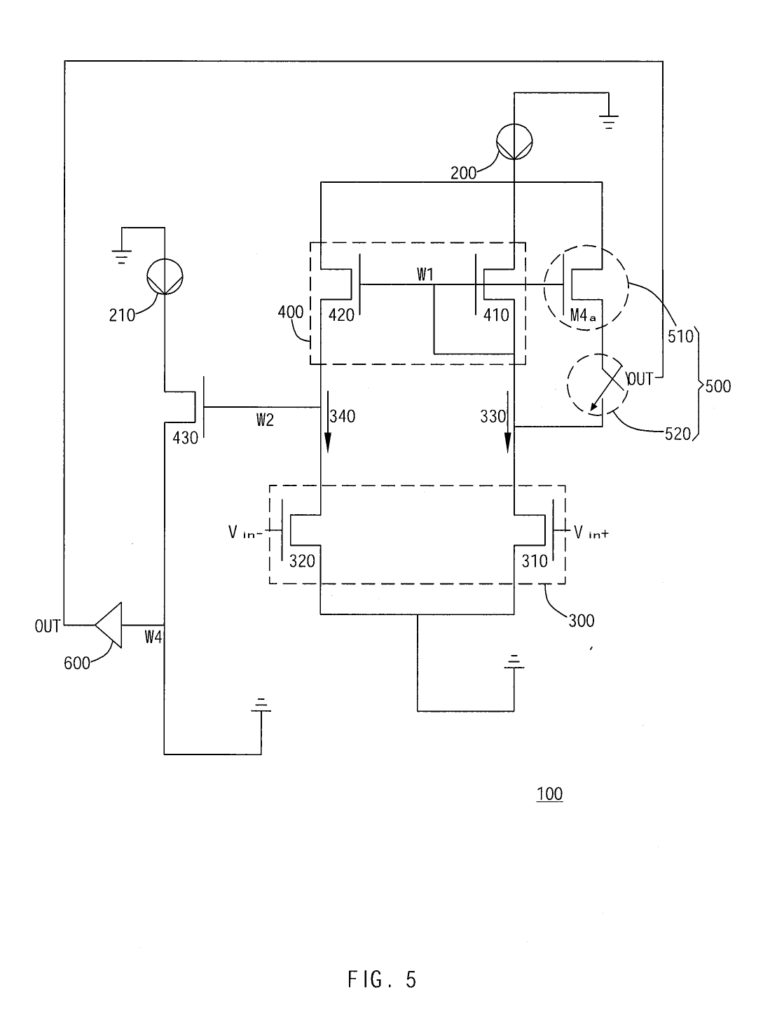

FIG. 4 and FIG. 5 are two variation embodiments of the voltage comparator 100 illustrated in FIG. 2. As FIG. 4 shows, the diverting portion 500 includes a diverting transistor 510 and a variable resistor 520, wherein the voltage across the variable resistor 520 is the analogue voltage at the fourth node W4. In other words, the analogue voltage at the fourth node W4 and the variable resistance of the diverting portion 500 dynamically regulates the ratio between currents flowing through the first output portion 410 and the diverting portion 500.

In the embodiment illustrated in FIG. 5, locations of the first current source 200 and the second current source 210 are different from those in the voltage comparator illustrated in FIG. 2. As shown in FIG. 5, the first current source 200 is electrically to the first output portion 410, the second output portion 420, and the diverting transistor 510. In different embodiments, the first current source 200 and the second current source 210 can be replaced by a combination of voltage sources and resistors. Furthermore, except the locations of the first current source 200 and the second current source 210, the voltage comparator illustrated in FIG. 5 is functionally and structurally identical to the voltage comparator illustrated in FIG. 2 and thus will not be further elaborated here.

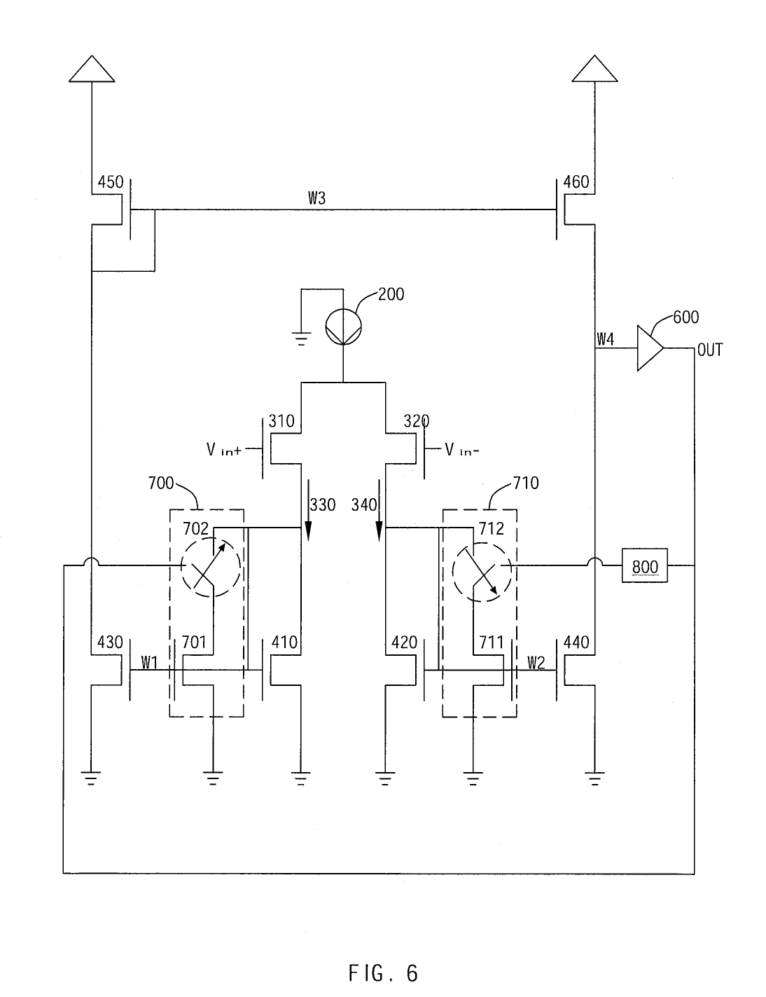

FIG. 6 illustrates another embodiment of the voltage comparator of the present invention. As FIG. 6 shows, the result output portion 400 includes the first output portion 410, the second output portion 420, the third output portion 430, and the fourth output portion 440, wherein the first output portion 410 and the third output portion 430 are used to process the first current 330 while the second output portion 420 and the fourth output portion 440 are used to process the second current 340. As shown in FIG. 6, the first output portion 410, the second output portion 420, the third output portion 430, and the fourth output portion 440 of the present embodiment are all MOSFETs, but are not limited thereto. As FIG. 6 shows, the first current 330 is inputted into the source and gate of the first output portion 410. In addition, the gate of the first output portion 410 and the gate of the third output portion 430 are connected to form a current mirror. In this way, the current passing through the first output portion 410 and the current passing through the third output portion 430 will be substantially identical in magnitude. Similarly, the gate of second output portion 420 and the gate of the fourth output portion 440 are connected to form another current mirror, wherein the current flowing through the second output portion 420 is substantially equal in magnitude to the current flowing through the fourth output portion 440.

The voltage comparator 100 of the present embodiment further includes a fifth output portion 450 and a sixth output portion 460, wherein the source of the third output portion 430 is electrically connected to the drain and the gate of the fifth output portion 450. In this way, the current flowing through the third output portion 430 and the current flowing through the fifth output portion 450 are substantially identical in magnitude. The drain and the gate of the fifth output portion 450 are electrically connected to the gate of the sixth output portion 460. As shown in FIG. 6, the electrical connection of the fifth output portion 450 and the six output portion 460 forms another current mirror. In this way, the current flowing through the fifth output portion 450 is substantially identical in magnitude to the current flowing through the third output portion 430. Furthermore, the current flowing through the sixth output portion 460 is also substantially in magnitude to those flowing through the third output portion 430 and the fifth output portion 450 due to the current mirror formed by the fifth output portion 450 and the six output portion 460. In other words, the voltage comparator 100 uses a plurality of current mirrors to duplicate the first current 330 and then outputs the first current 330 at different locations of the voltage comparator 100.

Furthermore, as FIG. 6 shows, the voltage comparator 100 further includes a first diverting portion 700 and a second diverting portion 710. The first diverting portion 700 is electrically connected to the first output portion 410 in parallel while the second diverting portion 710 is electrically connected to the second output portion 420 in parallel. The first diverting portion 700 includes a first diverting transistor 701 and a first switch 702 while the second diverting portion 710 includes a second diverting transistor 711 and a second diverting switch 712. The first diverting portion 700 and the second diverting portion 710 have substantially the same structure and the same function as those of the diverting portion illustrated in FIG. 2 and therefore will not be further elaborated here.

As FIG. 6 shows, the voltage comparator 100 further includes a phase shifter 800 used to accept the output signal OUT form the result transformation portion 600 and generate an inverted output signal. At any moment, the output signal OUT and the inverted output signal generated by the phase shifter 800 have substantially the same magnitude but different logic level. In the present embodiment, output signal OUT and the inverted output signal will be inputted into the first diverting switch 702 and the second diverting switch 712, respectively. The output signal OUT and the corresponding inverted output signal have opposite logic levels. In this way, one of the two signals will be at high level while the other signal is at low level. Correspondingly, at any moment, only one of the first diverting switch 702 and the second diverting switch 712 will conduct current. In the present embodiment, the first diverting switch 702 conducts when the output signal OUT is at high level while the second diverting switch 712 conducts when the output signal OUT is at low level.

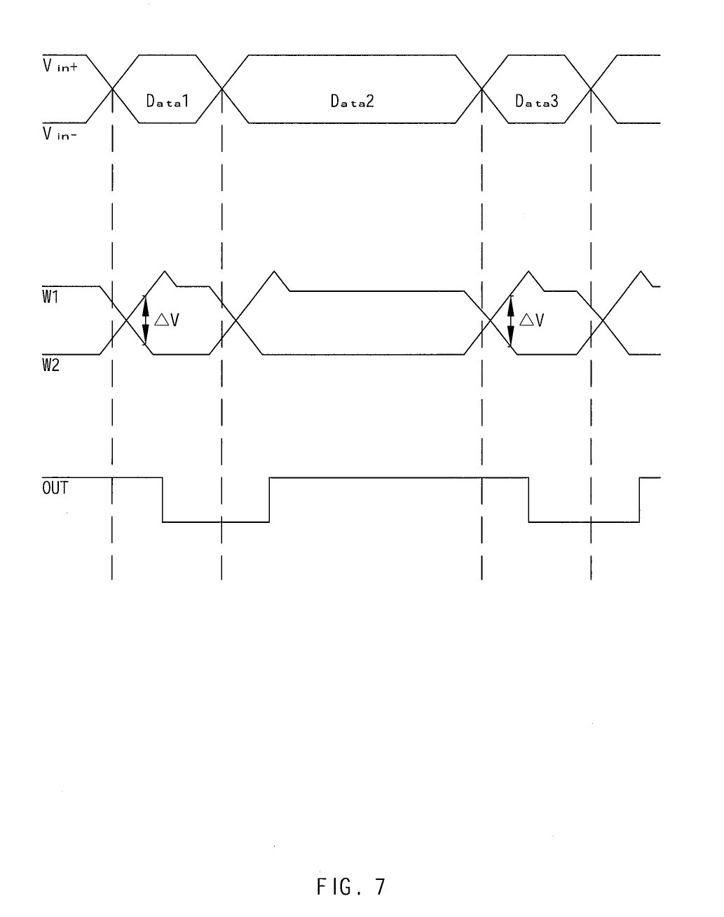

FIG. 7 is a timing diagram of the voltage comparator 100 illustrated in FIG. 6. FIG. 7 has illustrated the first voltage Vin+, the second voltage Vin−, the output voltage OUT, and voltages at the first node W1 and the second node W2. Here please refer to FIG. 6 and FIG. 7, in the duration of Data 1, the first voltage Vin+ is lower than the second voltage Vin−. Correspondingly, the first current 330 is reduced, allowing the discharge of the parasitic capacitance at the first node W1. On the other hand, the second current 340 is increased and then starts charging the parasitic capacitance at the second node W2. When the difference between the voltages at the first node W1 and the second node W2 reaches a threshold ΔV, the output signal OUT from the result transformation portion 600 will switch from high level to low level. At this time, the output signal OUT at low level will alter the first diverting switch 702 to an open status and increases the current received by the first output portion 410. Similarly, the inverted output signal from the phase shifter 800 will alter the second diverting switch 712 to a closed status so that a portion of the second current 340 can flow through the second diverting switch 712. This also reduces the amount of second current 340 flowing through the second output portion 420. Furthermore, the conduction of the second diverting switch 712 causes the parasitic capacitance at the second node W2 to discharge and reduces the voltage at the second node W2. Therefore, in the duration of Data 1, the voltage at the parasitic capacitance of the second node W2 is prevented from being charged indefinitely by the second current 340. In this way, in the duration of Data 2 where the first voltage Vin+ is higher than the second voltage Vin−, the charging of the first current 330 and the discharging of the second current 340 allows the voltage difference between the first node W1 and the second node W2 to reach the threshold ΔV earlier so that the switch of logic level of output signal OUT of the result transformation portion 600 requires less time. In other words, the output signal OUT requires less time to respond to the relationship change between the first voltage Vin+ and the second voltage Vin−.

On the other hand, when the first diverting switch 702 is closed and conducted, a portion of the first current 330 will flow through the first diverting portion 700. At this moment, the voltage at the first node W1 will stop accumulating due to the fact that a portion of the first current 330 is flowing through the first diverting portion 700. Similarly, when the second diverting switch 712 is closed and conducted, a portion of the second current 340 flows through the second diverting portion 710 and the voltage at the second node W2 will also stop accumulating.

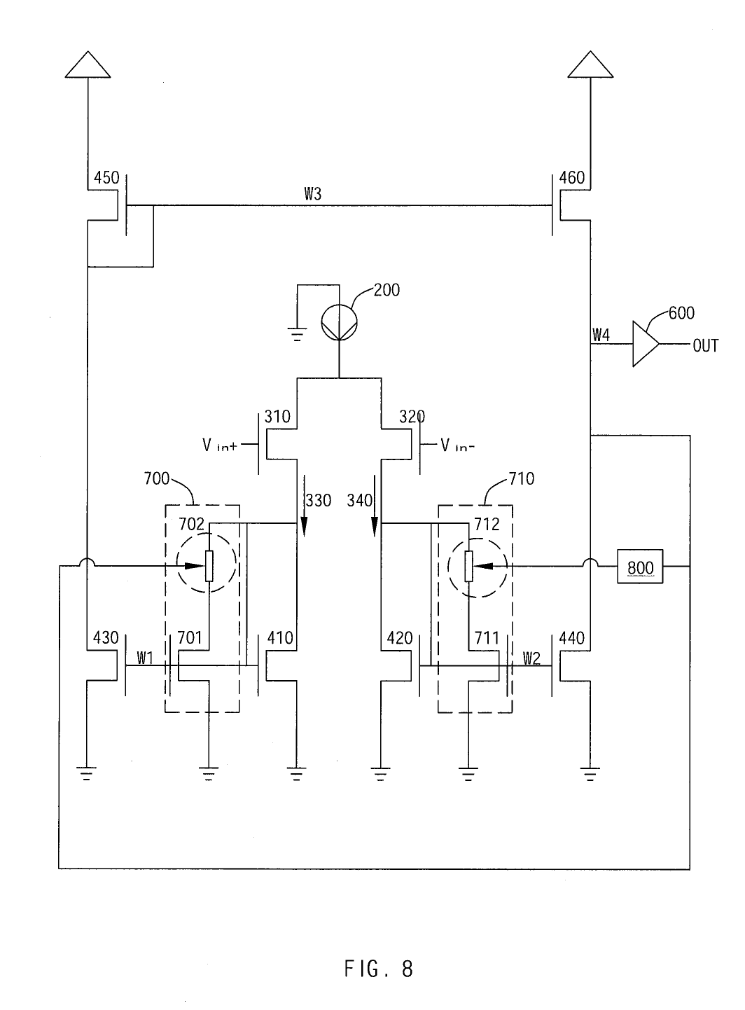

FIG. 8 is a variation embodiment of the voltage comparator 100 illustrated in FIG. 6. In the present embodiment, the first diverting portion 700 includes a first diverting transistor 701 and a first variable resistor 702 while the second diverting portion 710 includes a second diverting transistor 711 and a second variable resistor 712. The voltage at the first node W1 is inputted into the first variable resistor 702 and the phase shifter 800. The phase shifter 800 is connected to the node W4 and accepts the output signal OUT and generates an inverted output signal based on the output signal OUT, wherein the output signal OUT and the inverted output signal have different logic levels. This shows that the equivalent resistance of the first variable resistor 702 of the first diverting portion 700 and the equivalent resistance of the second variable resistor 712 of the second diverting portion 710 will be dynamically adjusted by the voltage at the second node W2. The equivalent resistance of the first diverting portion 700 changes continuously and therefore the current flowing through the first diverting portion 700 and the current flowing through the first output portion 410 will also change correspondingly. Similarly, the ratio between the current flowing through the first diverting portion 410 and the current flowing through the second output portion 420 will also change along with the change in equivalent resistance of the second diverting portion 710.

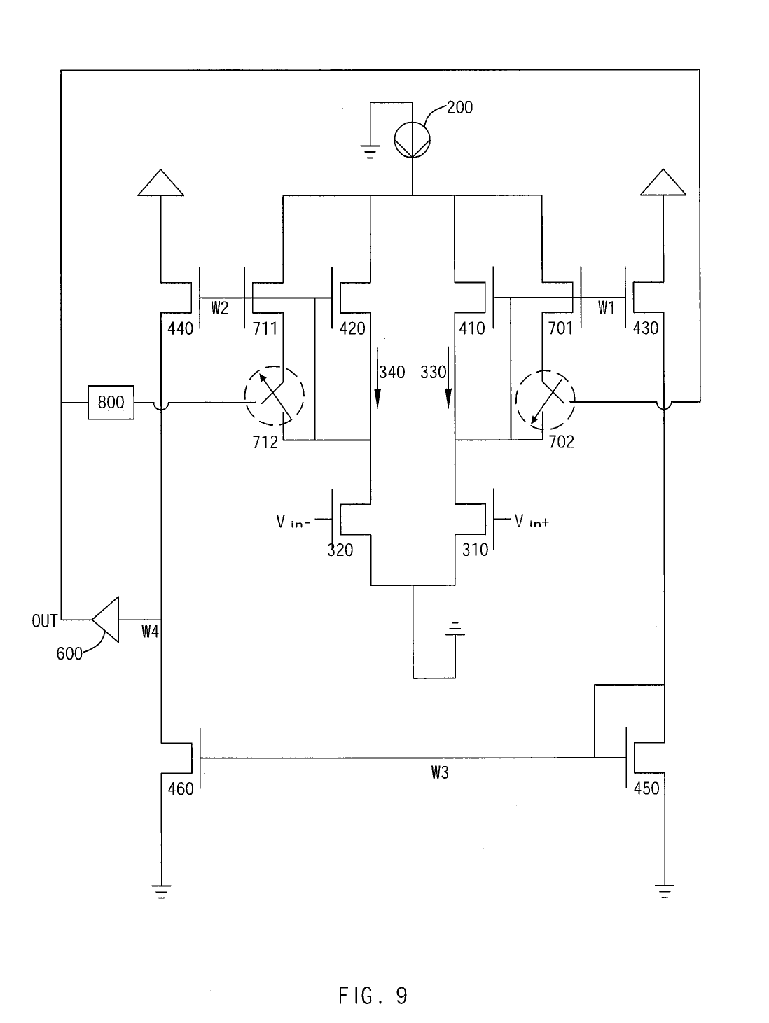

FIG. 9 is another variation embodiment of the voltage comparator 100 illustrated in FIG. 6. Locations of the first current source 200 and voltage supplies of the present embodiment are different from those illustrated in FIG. 6. The first current source 200 of the present embodiment is electrically connected to the first output portion 410, the second output portion 420, the first diverting transistor 701 and the second diverting transistor 711 whereas the first input portion 310 and the second input portion 320 are connected to the ground. In a different embodiment, the first current source 200 can be replaced by a combination of voltage sources and resistors. Except the location of the first current source 210, the voltage comparator 100 illustrated in FIG. 9 is functionally and structurally identical to the voltage comparator illustrated in FIG. 2 and thus will not be further elaborated here.

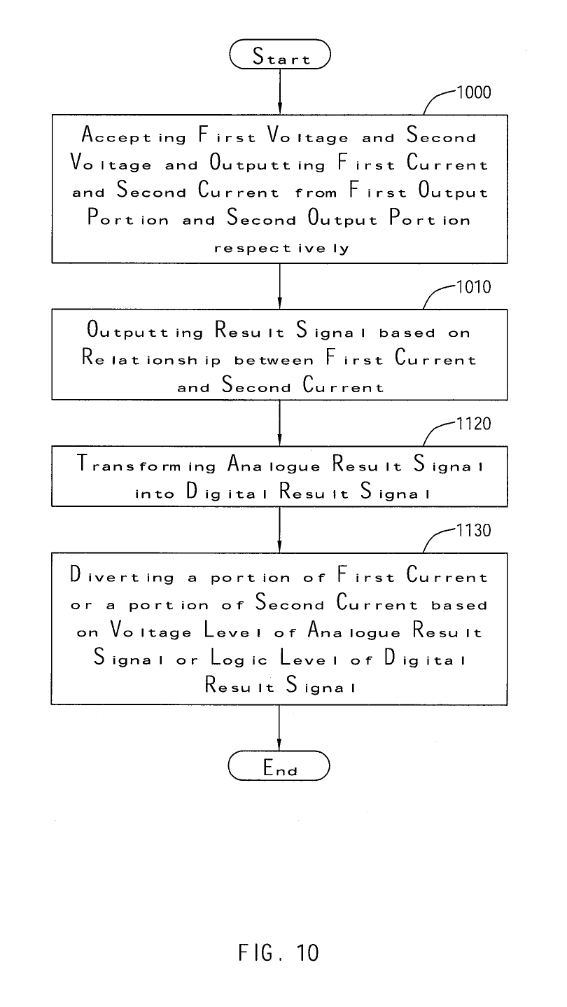

FIG. 10 is a flow chart of the transition acceleration method of a voltage comparator. As FIG. 10 shows, the transition acceleration method includes step 1000 of accepting a first voltage and a second voltage and outputting a first current and a second current from a first output portion and a second output portion, respectively. In the present embodiment, the first current is substantially directly proportional to the first voltage whereas the second current is substantially directly proportional to the second voltage. The transition acceleration method includes step 1010 of outputting a result signal based on a relationship between the first current and the second current. In the present embodiment, the first current and the second current will accumulate voltages at a first node and a second node of the voltage comparator, respectively. The voltage comparator includes a result output portion for outputting an analogue result signal, wherein the logic level of the analogue result signal represents the relationship between the first voltage and the second voltage. In addition, the amplitude of the analogue result signal is preferably the difference between the first voltage and the second voltage.

The transition acceleration method illustrated in FIG. 10 further includes step 1120 of transforming the analogue result signal into a digital result signal. The voltage comparator of the present embodiment includes a result transformation portion for transforming the analogue result signal into a digital result signal of high level or low level. In the present embodiment, the transition acceleration method includes step 1130 of diverting a portion the first current or a portion of the second current based on the voltage level of the analogue result signal or the logic level of digital result signal. In the present embodiment, when the digital result signal switches between logic levels, step 1130 will divert a portion of the first current or the second current and stop the accumulation of voltage at a corresponding node so that the voltage difference between the first node and the second node is prevented from becoming excessively huge. In this way, the voltage difference between the first node and the second node requires less time to reach the threshold for switching the logic level of the digital result signal. This shows that step 1130 can reduce the time required to switch the logic level of digital result signal which in turn improves the accuracy and speed of the voltage comparator.

The above is a detailed description of the particular embodiment of the invention which is not intended to limit the invention to the embodiment described. It is recognized that modifications within the scope of the invention will occur to a person skilled in the art. Such modifications and equivalents of the invention are intended for inclusion within the scope of this invention.

What is claimed is:

1. A voltage comparator for comparing a first voltage and a second voltage, the voltage comparator comprising:
an input portion, outputting a first current based on the first voltage and outputting a second current based on the second voltage;
an output portion, electrically connected to the input portion, for outputting a result signal based on the difference between the first current and the second current; and
a diverting portion, electrically connected to the input portion, for diverting a portion of the first current based on the result signal.

2. The voltage comparator of claim 1, wherein the input portion includes a first input portion for outputting the first current and a second input portion for outputting the second current, the diverting portion is electrically connected to the first input portion in parallel.

3. The voltage comparator of claim 1, wherein the input portion includes a first input portion for outputting the first current and a second input portion for outputting the second current, the diverting portion includes a first diverting portion connected to the first input portion in parallel and a second diverting portion connected to the second input portion in parallel.

4. The voltage comparator of claim 3, further comprising a phase shifter electrically connected to the output portion to receive the result signal and output an inverted result signal, wherein the result signal and the inverted result signal are inputted into the first diverting portion and the second diverting portion, respectively.

5. A liquid crystal display driver, comprising:
a voltage comparator for comparing a first voltage and a second voltage, the voltage comparator comprising:
an input portion, outputting a first current based on the first voltage and outputting a second current based on the second voltage;
an output portion, electrically connected to the input portion, for outputting a result signal based on a difference between the first current and the second current; and
a diverting portion, electrically connected to the output portion, for selectively diverting a portion of the first current based on the result signal.

6. The liquid crystal display driver of claim 5, wherein the input portion includes a first input portion for outputting the first current and a second input portion for outputting the second current, the diverting portion is electrically connected to the first input portion in parallel.

7. The liquid crystal display driver of claim 5, the input portion includes a first input portion for outputting the first current and a second input portion for outputting the second current, the diverting portion includes a first diverting portion connected to the first input portion in parallel and a second diverting portion connected to the second input portion in parallel.

8. The liquid crystal display driver of claim 7, further comprising a phase shifter electrically connected to the output portion to receive the result signal and output an inverted result signal, wherein the result signal and the inverted result signal are inputted into the first diverting portion and the second diverting portion, respectively.

9. A transition acceleration method for a voltage comparator, including the following steps:
accepting a first voltage and a second voltage and outputting a first current and a second current corresponding to the first voltage and the second voltage, respectively;
outputting a result signal based on a difference between the first current and the second current; and
diverting a portion of the first current based on the result signal.

10. The transition acceleration method of claim 9, wherein the step of outputting the first current and the second current includes outputting the first current from a first input portion and outputting the second current from a second input portion; and
the step of diverting the first current includes electrically connecting a diverting portion with the first input portion in parallel.

11. The transition acceleration method of claim 9, wherein the step of outputting the first current and the second current includes outputting the first current from a first input portion and outputting the second current from a second input portion;
the step of diverting the first current includes the following steps:
electrically connecting a first diverting portion to the first input portion and a second diverting portion to the second input portion;
generating an inverted result based on the result signal; and
inputting the result signal into the first diverting portion and inputting the inverted result signal into the second diverting portion.
